(19) United States
(12) Patent Application Publication
(10) Pub. No.: US 2010/0109010 A1
(43) Pub. Date: May 6, 2010

(54) DISPLAY DEVICE

(75) Inventors: Hidekazu MIYAKE, Mobara (JP); Takuo Kaitoh, Mobara (JP); Terunori Saitou, Mobara (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(73) Assignee: Hitachi Displays, Ltd.

(21) Appl. No.: 12/608,193

(22) Filed: Oct. 29, 2009

(30) Foreign Application Priority Data
Oct. 31, 2008 (JP) 2008-282183

(51) Int. Cl. H01L 33/00

(52) U.S. Cl. 257/59; 257/72; 257/E33.053

(57) ABSTRACT

A display device having thin film transistors which can efficiently suppress an OFF-leak current while suppressing the decrease of an ON current is provided. The display device includes an insulation substrate, and thin film transistors which are formed on the insulation substrate. Each thin film transistor includes a conductive layer on which a gate electrode is formed, a first insulation layer which is formed on the conductive layer, a semiconductor layer which is formed on the first insulation layer and has a first semiconductor film thereof formed above the gate electrode, the first semiconductor film having a first region and a second region which are spaced apart from each other on an upper surface thereof, a first electrode which is connected to the upper surface of the first semiconductor film via the first region, and a second electrode which is connected to the upper surface of the first semiconductor film via the second region. A portion of the gate electrode which is covered with the first semiconductor film is arranged closer to the first region than the second region.

The present application claims priority from Japanese application JP 2008-282183 filed on Oct. 31, 2008, the content of which is hereby incorporated by reference into this application.

### BACKGROUND OF THE INVENTION

1. Field of the Invention

The present invention relates to a display device, and more particularly to a display device which includes thin film transistors.

2. Description of the Related Art

Recently, with respect to a thin film transistor used in a display device such as a liquid crystal display device, various structures have been studied for enhancing electric characteristics of the thin film transistor. FIG. 15 is a cross-sectional view showing one example of the structure of a conventional thin film transistor. The thin film transistor shown in the drawing is a bottom-gate-type thin film transistor. A gate electrode GT is formed on a lower protective insulation film GN formed on an insulation substrate SUB. A semiconductor film SC is formed on a gate insulation film GI and above the gate electrode. A source semiconductor film SD and a drain semiconductor film DD are formed on the semiconductor film SC. These two semiconductor films are formed of a semiconductor film in which impurities such as phosphorous are diffused. The source electrode ST is connected to the semiconductor film SC via the source semiconductor film SD, while the drain electrode DT is connected to the semiconductor film SC via the drain semiconductor film DD. Here, the gate electrode GT is arranged close to the source semiconductor film SD (and the source electrode ST) and the drain semiconductor film DD (and the drain electrode DT) in a state that the gate electrode GT overlaps with the source semiconductor film SD and the drain semiconductor film DD respectively to the same extent as viewed in a plan view. The above-mentioned structure is covered with a protective insulation film PA.

JP-A-2001-102584 (Patent Document 1) discloses a thin film transistor having the above-mentioned structure.

### SUMMARY OF THE INVENTION

It has been known that such a thin film transistor has a drawback that an electric current (an OFF-leak current) is generated and flows in the thin film transistor when a switch is turned off. As one of methods which can cope with this drawback, considered is a method which sets the gate electrode GT and the source electrode ST (first region) remoter from each other and, at the same time, sets the gate electrode GT and the drain electrode DT (second region) remoter from each other in symmetry. FIG. 16 shows an example of the structure which copes with the drawback. The distance between the source electrode ST and the gate electrode GT is increased, and the distance between the drain electrode DT and the gate electrode GT is also increased in the same manner. However, such structure decreases an electric field which the gate electrode GT applies to a channel region of the thin film transistor and hence, there arises a drawback that an ON current which flows at a point of time that a switch of the thin film transistor is turned on is also decreased.

The invention has been made in view of these drawbacks, and it is an object of the invention to provide a display device including thin film transistors which can efficiently suppress an OFF-leak current while suppressing the decrease of an ON current.

To briefly explain the summary of typical inventions among the inventions described in this specification, they are as follows.

According to one aspect of the invention, there is provided a display device which includes: an insulation substrate; and thin film transistors which are formed on the insulation substrate, wherein each thin film transistor includes: a conductive layer on which a gate electrode is formed; a first insulation layer which is formed on the conductive layer; a semiconductor layer which is formed on the first insulation layer and has a first semiconductor film thereof formed above the gate electrode, the first semiconductor film having a first region and a second region which are spaced apart from each other on an upper surface thereof; a first electrode which is connected to the upper surface of the first semiconductor film via the first region; and a second electrode which is connected to the upper surface of the first semiconductor film via the second region; wherein a portion of the gate electrode which is covered with the first semiconductor film is arranged closer to the first region than the second region.

In one mode of the invention, the gate electrode may overlap with the first region as viewed in a plan view and may not overlap with the second region as viewed in a plan view.

In one mode of the invention, the first semiconductor film may be made of a material which contains poly-crystalline silicon or micro-crystalline silicon.

In one mode of the invention, the first electrode may be connected to the upper surface of the first semiconductor film via a second semiconductor film formed on the first region, and the second electrode may be connected to the upper surface of the first semiconductor film via a third semiconductor film formed on the second region.

In one mode of the invention, impurities may be diffused in the second semiconductor film and the third semiconductor film.

In one mode of the invention, at least one of the first electrode and the second electrode may be connected to a side surface of the first semiconductor film via a semiconductor film in which the impurities are diffused.

In one mode of the invention, the first electrode may be a source electrode of the thin film transistor, and the second electrode may be a drain electrode of the thin film transistor.

In one mode of the invention, the first semiconductor film may be formed of two layers consisting of a poly-crystalline silicon film and an amorphous silicon film stacked from a first insulation layer side.

In one mode of the invention, the first semiconductor film may be formed of two layers consisting of a micro-crystalline silicon film and an amorphous silicon film stacked from a first insulation layer side.

In one mode of the invention, an insulation film may be formed on an upper layer of a region sandwiched by the first region and the second region.

In one mode of the invention, a display region which includes a plurality of pixels and a peripheral region which surrounds the display region may be formed on the insulation substrate, and the thin film transistor may be formed on the peripheral region.

In one mode of the invention, the pixel may include a plurality of sub pixels, and the thin film transistor may be a changeover switch which selects a sub pixel to which a video signal is inputted out of the plurality of sub pixels.

In one mode of the invention, the first electrode may be connected to the sub pixel, and a video signal may be inputted to the second electrode.

According to the invention, it is possible to efficiently suppress an OFF-leak current while suppressing the decrease of an ON current.

### BRIEF DESCRIPTION OF THE DRAWING

FIG. 1 is a view showing an equivalent circuit of a display region and a region around the display region on an array substrate according to an embodiment of the invention;

FIG. 2 is a partially enlarged view showing an example of a pixel region and a peripheral drive circuit on the array substrate according to the embodiment of the invention;

FIG. 3 is a plan view showing one example of a thin film transistor according to the embodiment of the invention;

FIG. 4 is a cross-sectional view of the thin film transistor taken along a line A-A in FIG. 3;

FIG. 5 is a view showing a manufacturing step of a TFT substrate according to the embodiment of the invention;

FIG. 6 is a view showing a manufacturing step of the TFT substrate according to the embodiment of the invention;

FIG. 7 is a view showing a manufacturing step of the TFT substrate according to the embodiment of the invention;

FIG. 8 is a view showing a manufacturing step of the TFT substrate according to the embodiment of the invention;

FIG. 9 is a view showing a manufacturing step of the TFT substrate according to the embodiment of the invention;

FIG. 10 is a cross-sectional view showing the thin film transistor of another example according to the embodiment of the invention;

FIG. 11 is a cross-sectional view showing the thin film transistor of another example according to the embodiment of the invention;

FIG. 12 is a cross-sectional view showing the thin film transistor of another example according to the embodiment of the invention;

FIG. 13 is a plan view showing the thin film transistor of another example according to the embodiment of the invention;

FIG. 14 is a cross-sectional view taken along a line B-B in FIG. 13;

FIG. 15 is a cross-sectional view showing one example of a conventional thin film transistor; and

FIG. 16 is a view for explaining a task for which the thin film transistor of the invention is provided.

### DESCRIPTION OF THE PREFERRED EMBODIMENT

Hereinafter, an embodiment of the invention is explained in detail in conjunction with drawings. A display device according to the embodiment of the invention is a vertical-electric-field-type liquid crystal display device such as a TN-type liquid crystal display device, and includes an array substrate, a filter substrate which faces the array substrate in an opposed manner and forms color filters thereon, a liquid crystal material which is sealed in a region sandwiched between both substrates, and a driver IC which is mounted on the array substrate. Both the array substrate and the filter substrate are formed of a glass substrate or the like.

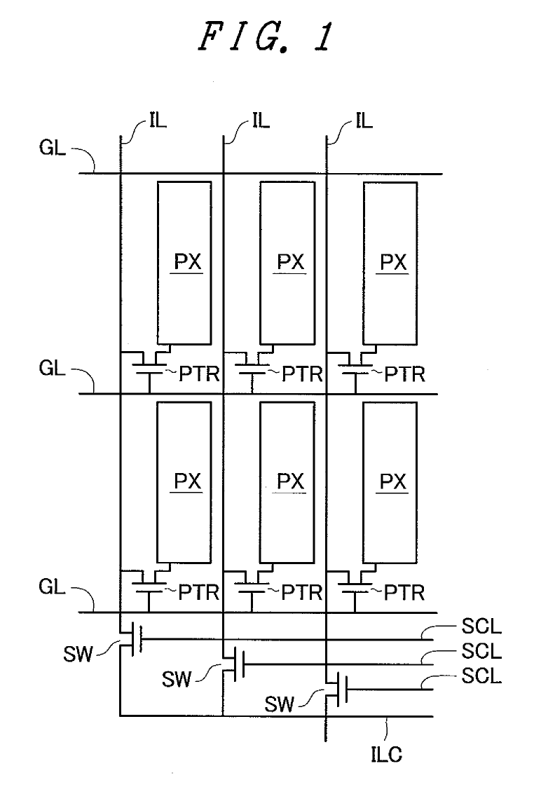

FIG. 1 is a view showing an equivalent circuit of a display region and a region around the display region on the array substrate according to the embodiment of the invention. In the display region of the array substrate, a large number of gate signal lines GL extend in the lateral direction and are arranged parallel to each other in the longitudinal direction, and a large number of video signal lines IL extend in the longitudinal direction and are arranged parallel to each other in the lateral direction. Further, the display region is defined in a matrix array by the gate signal lines GL and the video signal lines IL so as to form a plurality of defined regions, and each defined region constitutes one pixel region. A pixel transistor PTR is arranged in each pixel region. The pixel transistor PTR is a so-called bottom-gate-type thin film transistor, wherein a gate electrode of the pixel transistor PTR is connected to the gate signal line GL, one of a source electrode and a drain electrode of the pixel transistor PTR is connected to the video signal line IL, and the other of the source electrode and the drain electrode is connected to a pixel electrode PX. One pixel region corresponds to one sub pixel out of red, green and blue sub pixels which constitute one pixel. One pixel is constituted of three pixel regions which are arranged adjacent to each other in the lateral direction corresponding to R, G and B. In this embodiment, the arrangement of RGB of the sub pixels is determined for every column. One video signal input line ILC is allocated to amass of pixels in one column. That is, one video signal input line ILC is provided for every three columns of pixel regions. The selection of pixel regions corresponding to R, G or B to which a signal is supplied from the video signal line IL is controlled by RGB changeover switches SW. A switch control line SCL is connected to a gate electrode of each RGB changeover switch SW. Here, in the drawing, among the pixel regions which are arranged in a matrix array so as to form the display region, only 2×3 pixel regions are shown.

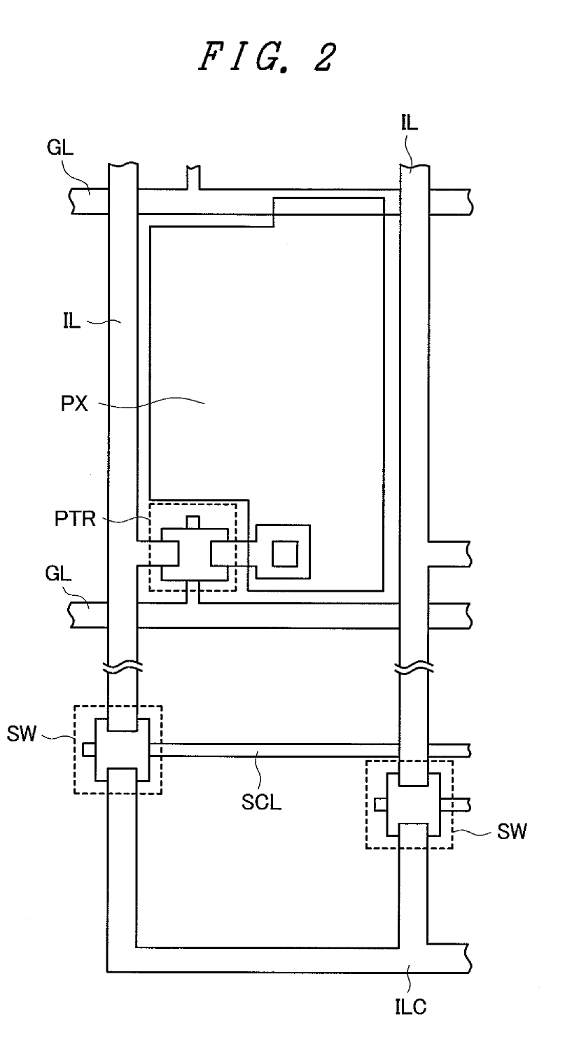

FIG. 2 is a partially enlarged view showing an example of a pixel region and a peripheral drive circuit on the array substrate according to the embodiment of the invention. As has been explained in conjunction with FIG. 1, the display region is defined in a matrix array by the gate signal lines GL and the video signal lines IL so as to form the plurality of defined regions, and each defined region constitutes one pixel region. The pixel electrode PX is formed of a transparent electrode, and one pixel electrode PX is arranged in one pixel region. The RGB changeover switch SW is formed of a bottom-gate-type thin film transistor. A gate electrode of the RGB changeover switch SW is connected to the switch control line SCL, a source electrode of the RGB changeover switch SW is connected to the pixel transistor PTR of each pixel via the video signal line IL, and a drain electrode of the RGB changeover switch SW is connected to the video signal input line ILC. Here, the RGB changeover switches SW are arranged outside the display region of the array substrate so that there is no possibility that light from a backlight is radiated to the RGB changeover switches SW.

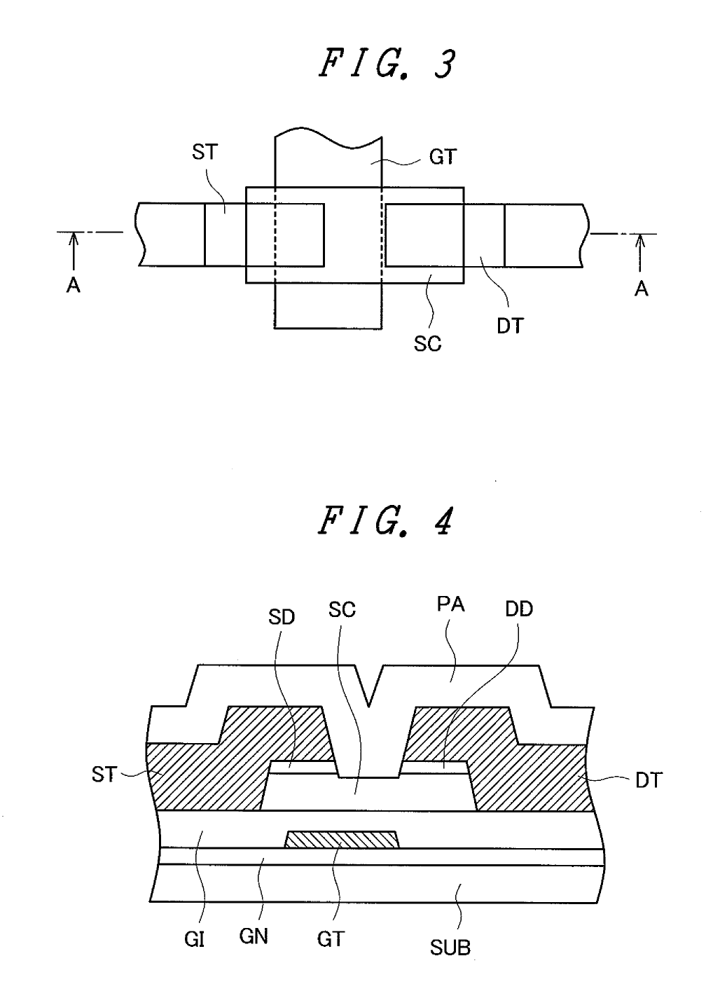

FIG. 3 is a view showing one example of the thin film transistor according to the embodiment of the invention. To be more specific, FIG. 3 shows the RGB changeover switch SW in FIG. 2. The gate electrode GT extends in the vertical direction in the drawing at a center portion of the thin film transistor, and has an upper portion thereof connected to the switch control line SCL not shown in the drawing. A semiconductor film SC is formed so as to cover the gate electrode GT, and has a laterally-elongated rectangular shape. A right end portion of the source electrode ST is formed so as to overlap with a left portion of the semiconductor film SC as viewed in a plan view. An overlapping portion has a rectangular shape defined by a left side of the semiconductor film SC and an upper side, a lower side and a right side of the source electrode ST in the drawing. The source electrode ST extends toward a left side of the drawing, and an extending end of the source electrode ST is connected to the video signal line IL. The drain electrode DT is formed such that a left end portion of the drain electrode DT is spaced apart from the source electrode ST and overlaps with a right portion of the semiconductor film SC as viewed in a plan view. An overlapping portion has a rectangular shape defined by a right side of the semiconductor film SC and an upper side, a lower side and a left side of the drain electrode DT in the drawing. The drain electrode DT extends toward a right side of the drawing, and an extending end of the drain electrode DT is connected to the video signal input line ILC. The gate electrode GT overlaps with the source electrode ST, and does not overlap with the drain electrode DT as viewed in a plan view.

FIG. 4 is a cross-sectional view of the thin film transistor taken along a line A-A in FIG. 3. The thin film transistor is formed over an insulation substrate SUB as well as over a lower protective insulation film GN which is formed on the insulation substrate SUB. The insulation substrate SUB is formed of a glass substrate. The gate electrode GT is formed on the insulation substrate SUB, and a gate insulation film GI is formed on the gate electrode GT and on a portion of the lower protective insulation film GN on which the gate electrode GT is not formed. The semiconductor film SC is formed on the gate insulation film GI and above the gate electrode GT. The semiconductor film SC constitutes a channel region of the thin film transistor. The semiconductor film SC is mainly made of poly-crystalline silicon (p-Si) or micro-crystalline silicon (μc-Si). Here, the micro-crystalline silicon means crystalline silicon having a crystal grain size of approximately 10 nm to 100 nm. Here, poly-crystalline silicon is also one kind of crystalline silicon.

A source semiconductor film SD is formed on a left portion (first region) of an upper surface of the semiconductor film SC in a contact state, and a drain semiconductor film DD is formed on a right portion (second region) of the upper surface of the semiconductor film SC in a contact state. The first region and the second region are spaced apart from each other. The source semiconductor film SD and the drain semiconductor film DD are formed of an n-type semiconductor film in which impurities such as phosphorous are diffused. The source electrode ST (first electrode) is formed so as to cover the source semiconductor film SD from above, the source electrode ST is brought into contact with a left side wall of the semiconductor film SC in the drawing, and extends on the gate insulation film GI where the semiconductor film SC is not formed toward a left side of the drawing. The drain electrode DT (second electrode) is formed so as to cover the drain semiconductor film DD from above, the drain electrode DT is brought into contact with a right side wall of the semiconductor film SC in the drawing, and extends on the gate insulation film GI where the semiconductor film SC is not formed toward a right side of the drawing. Here, the source electrode ST and the drain electrode DT are not brought into direct contact with an upper surface of the semiconductor film SC. A protective insulation film PA is formed on such structure.

Here, as has been explained in conjunction with FIG. 3, the gate electrode GT and the source electrode ST overlap with each other as viewed in a plan view, and the gate electrode GT and the drain electrode DT do not overlap with each other. Further, as shown in FIG. 4, the gate electrode GT overlaps also with the source semiconductor film SD or a first region which is formed below the source electrode ST as viewed in a plan view, and does not overlap with the drain semiconductor film DD or a second region which is formed below the drain electrode DT as viewed in a plan view. Accordingly, a portion of the gate electrode GT which overlaps with the semiconductor film SC as viewed in a plan view is arranged closer to the source electrode ST and the first region than the drain electrode DT and the second region.

Due to such structure, it is possible to decrease an electric current (OFF-leak current) which flows when a switch is turned off. The reason why the electric current can be decreased is explained hereinafter. Firstly, considered is a case where a negative potential is applied to the gate electrode GT, a positive potential is applied to the drain electrode DT, and a negative potential is applied to the source electrode ST when the switch is turned off. This case corresponds to a state where a positive potential is applied to the drain electrode ST from the video signal input line ILC, and a negative potential is applied to the source electrode ST from a capacitance held by the pixel electrode PX via a pixel transistor PTR. Here, it is considered that a potential difference between the gate electrode GT and the drain electrode DT is larger than a potential difference between the gate electrode GT and the source electrode ST and hence, an OFF-leak current is liable to be generated in the portion between the gate electrode GT and the drain electrode DT in general. However, in the thin film transistor according to this embodiment, a distance between the gate electrode GT and the second region is large in the inside of the semiconductor film SC and hence, an actual electric field generated in such a portion is alleviated. Accordingly, it is possible to suppress the generation of a leak current between the gate electrode GT and the drain electrode DT and also the generation of an. OFF-leak current in the thin film transistor per se. On the other hand, the gate electrode GT and the first region can be arranged close to each other and hence, it is also possible to ensure a width of the gate electrode. Due to such constitution, a quantity of electric field which is applied to channel from the gate electrode GT can be ensured thus suppressing the decrease of an ON current.

Next, considered is a case where the polarity of the potential supplied from the video signal input line ILC is inverted. In this case, a negative potential is applied to the gate electrode GT, a positive potential is applied to the source electrode ST, and a negative potential is applied to the drain electrode DT. Here, a potential difference between the source electrode ST and the gate electrode GT which are not arranged remote from each other becomes larger than a potential difference between the gate electrode GT and the source electrode ST and hence, the generation of an OFF-leak current per se cannot be suppressed. However, the potential which is applied to the source electrode ST is a potential supplied from the capacitance held by the pixel electrode PX and hence, an absolute value of the potential is smaller than the positive potential which is applied to the drain electrode DT in the above-mentioned case. This is because the potential of the pixel electrode PX is a potential held at a point of time that the potential supplied from the video signal input line ILC is positive and when the switch is turned on, and the potential applied to the pixel electrode PX at this point of time is set to a potential lowered by an amount corresponding to a path through the RGB changeover switch SW, the pixel transistor PTR, the line resistances and the like. Accordingly, the increase of an absolute amount of an OFF-leak current here is limited so that the OFF-leak current can be suppressed as a whole when considering the former case and the latter case. Here, although the explanation is made using the absolute potential for facilitating the explanation, it is needless to say that the same advantageous effects can be acquired provided that the relative potential relationship satisfies the substantially same condition. Further, as described above, with respect to the display device, and more particularly with respect to the liquid crystal display device, there may be a case where polarity of a voltage applied to the electrode of the thin film transistor is inverted by frame inversion driving, line inversion driving, dot inversion driving or the like. Accordingly, the source electrode and the drain electrode of the thin film transistor are not originally determined univocally but are exchanged correspondingly to the polarity of an applied voltage.

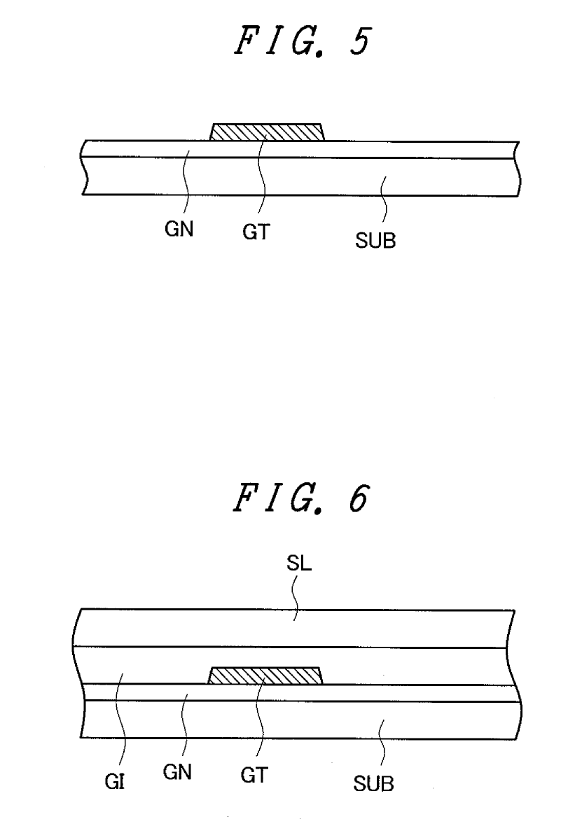

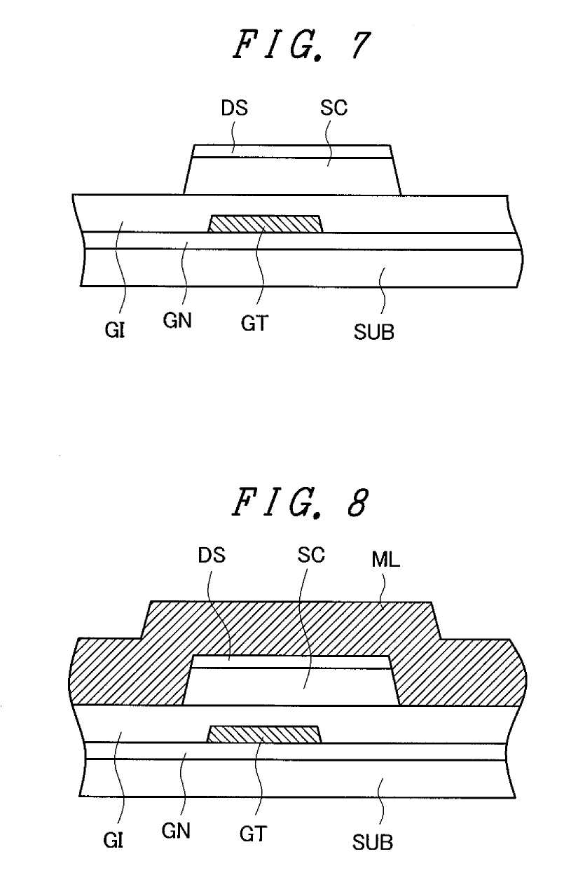

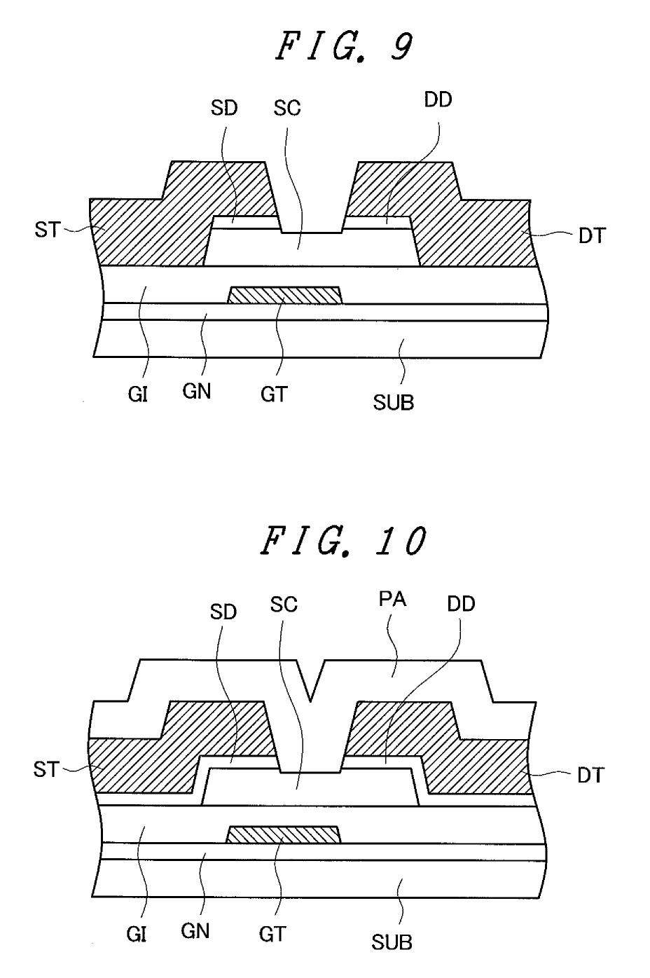

FIG. 5 to FIG. 9 are views showing the steps of manufacturing the array substrate according to the embodiment of the invention. Firstly, for example, a silicon nitride film having a thickness of 50 to 150 nm is formed on the insulation substrate SUB using a CVD method or the like thus forming the lower protective insulation film GN. Next, a metal film for forming the gate electrode GT which is made of, for example, high-melting-point metal such as molybdenum, tungsten or tantalum, or an alloy of these metals and has a thickness of 50 to 150 nm is formed. Then, the metal film is patterned by a photolithography and etching technique (FIG. 5) thus forming the gate electrode GT. Thereafter, a silicon oxide film, a silicon nitride film or a stacked film constituted of a silicon oxide film and a silicon nitride film and having a thickness of approximately 100 to 350 nm is formed thus forming the gate insulation film GI and, successively, the semiconductor layer SL containing amorphous silicon (a-Si) or crystalline silicon such as polycrystalline silicon or microcrystalline silicon is formed on the gate insulation film GI. Here, the crystalline silicon film may be formed by forming an amorphous silicon film and, thereafter, by crystallizing the amorphous silicon film (FIG. 6). Thereafter, for forming an impurity diffusion semiconductor film DS (n+ layer), for example, an amorphous silicon film having a thickness of 10 to 50 nm in which high-concentration phosphorous is diffused is formed, and the amorphous silicon film is patterned together with the semiconductor layer SL by a photolithography and etching technique (FIG. 7). Due to such treatment, the semiconductor film SC and the impurity diffusion semiconductor film DS are formed. Next, for example, a metal film ML having a thickness of approximately 300 to 500 nm is formed by sputtering metal such as aluminum or an aluminum alloy (FIG. 8). Here, for preventing the diffusion of the aluminum film and for decreasing a contact resistance, a layer (barrier metal layer) made of a high-melting-point metal such as titanium, molybdenum or an alloy of these metals is formed above and below the aluminum layer. A thickness of the barrier metal layer may be set to approximately 30 to 100 nm. Thereafter, the source electrode ST and the drain electrode DT are formed by a photolithography and etching technique (FIG. 9). The patterning using the photolithography technique in such a step is performed such that the source electrode ST is arranged to overlap with the gate electrode GT, and the drain electrode DT is arranged not to overlap with the gate electrode GT. Further, for forming the channel region in the semiconductor film SC, the impurity diffusion semiconductor film DS is also etched at this point of time. Next, as the protective insulation film PA, a silicon nitride film having a thickness of approximately 100 to 300 nm is formed using a CVD method, for example, and a contact hole and the like are formed thus completing the array substrate (FIG. 4).

FIG. 10 is a cross-sectional view showing another example (modification 1) of the thin film transistor according to the embodiment of the invention. Here, in the modification 1, a planar shape of the thin film transistor is substantially equal to the planar shape of the thin film transistor shown in FIG. 3. In the modification 1, a main point which makes this modification different from the example shown in FIG. 4 lies in that a source semiconductor film SD is brought into contact with a side wall of a semiconductor film SC on a left side of the drawing, and the drain semiconductor film DD is brought into contact with a side wall of the semiconductor film SC on a right side of the drawing. Here, connection destinations of a gate electrode GT, a source electrode ST and a drain electrode DT are equal to the corresponding connection destinations in the above-mentioned example.

The structure of the thin film transistor of the modification 1 is specifically explained hereinafter. The thin film transistor of the modification 1 is substantially equal to the thin film transistor of the example 4 with respect to the structure below the gate insulation film GI and the formation of the semiconductor film SC above the gate insulation film GI. A first region which is brought into contact with the source semiconductor film SD is formed on a left portion of an upper surface of the semiconductor film SC, and a second region which is brought into contact with the drain semiconductor film DD is formed on a right portion of the upper surface of the semiconductor film SC. The first region and the second region are spaced apart from each other. The source semiconductor film SD has a right end thereof arranged on the first region, extends along the side wall of the semiconductor film SC on a left side of the drawing in a contact state from the first region, and further extends on the gate insulation film GI toward a left side of the drawing from an area in the vicinity of a lower end of the left side wall. The drain semiconductor film DD has a left end thereof arranged on the second region, extends along the side wall of the semiconductor film SC on a right side of the drawing in a contact state from the second region, and further extends on the gate insulation film GI toward a right side of the drawing from an area in the vicinity of the lower end of the right side wall. The source electrode ST is formed on the source semiconductor film SD, and the drain electrode DT is formed on the drain semiconductor film DD. Further, as viewed in a plan view, a portion of the gate electrode GT which overlaps with the semiconductor film SC overlaps with the first region and does not overlap with the second region. Here, the source electrode ST and the drain electrode DT are not brought into direct contact with the upper surface of the semiconductor film SC. The protective insulation film PA is formed so as to cover the above-mentioned structure.

By adopting the constitution shown in FIG. 10, a contact area of the source semiconductor film SD and a contact area of the drain semiconductor film DD which are brought into contact with the semiconductor film SC which constitutes the channel region of the thin film transistor are increased and hence, this modification 1 has an advantage that an ON current is increased compared to the previous embodiment which adopts the constitution shown in FIG. 4.

In manufacturing the thin film transistor having the constitution shown in FIG. 10, it is sufficient to change a part of the steps which are explained in conjunction with FIG. 5 to FIG. 9 as the manufacturing method of the thin film transistor having the constitution shown in FIG. 4. To be more specific, after forming the semiconductor layer SL (FIG. 6), patterning and the formation of the impurity diffusion semiconductor film DS may be performed and, thereafter, steps corresponding to the steps shown in FIG. 8 and succeeding drawings may be performed.

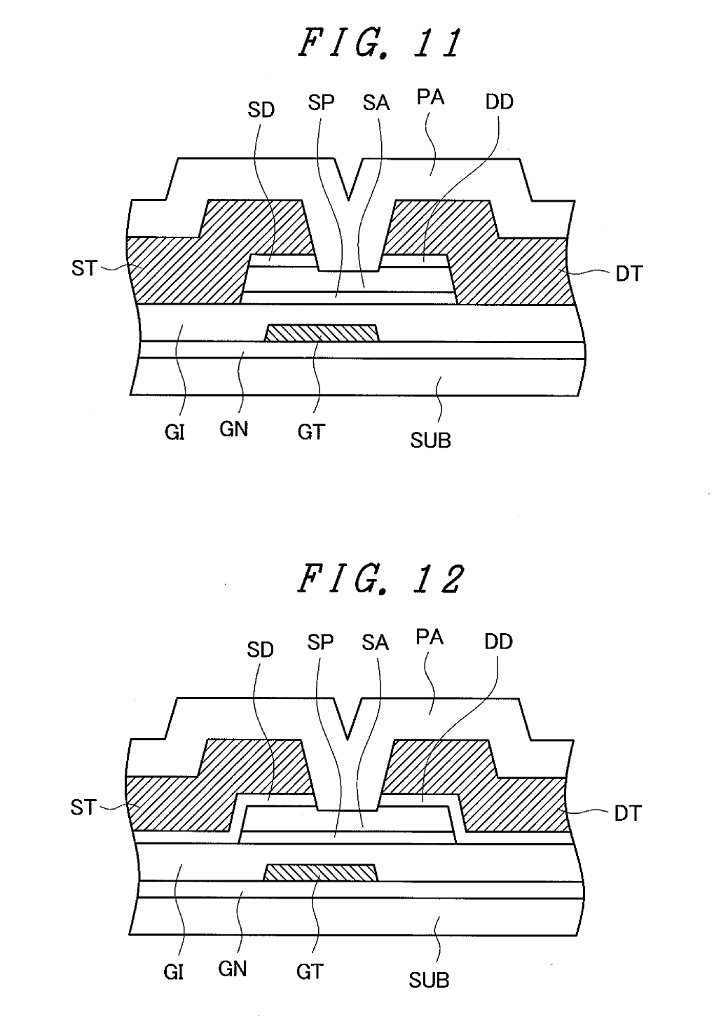

FIG. 11 is a cross-sectional view showing a thin film transistor of another example (modification 2) according to the embodiment of the invention. Here, in the modification 2, a planar shape of the thin film transistor of the modification 2 is substantially equal to the planar shape of the thin film transistor shown in FIG. 3. A main point which makes this modification 2 different from the other modifications lies in that a film which corresponds to the semiconductor film SC in the example shown in FIG. 4 is formed of a two-layered film consisting of a crystalline silicon film SP and an amorphous silicon film SA which is formed on the crystalline silicon film SP. These two layers form a channel region of the thin film transistor.

The structure of the thin film transistor of the modification 2 is specifically explained hereinafter. The structure below a gate insulation film GI is substantially equal to the corresponding structure of the example shown in FIG. 4. The two-layered film is formed by stacking the crystalline silicon film SP and the amorphous silicon film SA on the gate insulation film GI and above the gate electrode GT in this order. Here, the two-layered film has a rectangular shape as viewed in a plan view. A source semiconductor film SD is formed on a left portion (first region) of an upper surface of the amorphous silicon film SA in a contact state, and a drain semiconductor film DD is formed on a right portion (second region) of the upper surface of the amorphous silicon film SA in a contact state. The first region and the second region are spaced apart from each other. The source semiconductor film SD and the drain semiconductor film DD are formed of an n-type semiconductor film in which impurities such as phosphorous are diffused. A right end portion of the source electrode ST is arranged on the source semiconductor film SD. The source electrode ST extends along a side wall of the two-layered film on a left side of the drawing from the source semiconductor film SD in a contact state, and further extends on the gate insulation film GI toward a left side of the drawing from an area in the vicinity of a lower end of the side wall. A left end portion of the drain electrode DT is arranged on the drain semiconductor film DD. The drain electrode DT extends along a side wail of the two-layered film on a right side of the drawing from the drain semiconductor film DD in a contact state, and further extends on the gate insulation film GI toward a right side of the drawing from an area in the vicinity of the lower end of the side wall. Here, the source electrode ST and the drain electrode DT are not brought into direct contact with the upper surface of the semiconductor film SC. Further, as viewed in a plan view, a portion where the gate electrode GT, the crystalline silicon film SP and the like overlap with each other overlaps with the first region and does not overlap with the second region. A protective insulation film PA is formed so as to cover the above-described structure.

By adopting the constitution shown in FIG. 11, it is possible to decrease a leak current from a back channel of the thin film transistor. Here, the back channel means a portion of the channel region arranged close to the protective insulation film PA. In the channel region, a region where an electric current mainly flows is a region in the vicinity of the gate insulation film GI which is arranged close to the gate electrode GT and hence, the back channel is also referred to as a region of the channel region on a side opposite to the gate insulation film GI. It is considered that a leak current from the back channel is caused by a fixed charge generated in crystalline silicon which is brought into contact with the protective insulation film PA made of silicon nitride or the like. In this modification, the back channel is formed using amorphous silicon and hence, it is possible to suppress the generation of the fixed charge and the generation of a leak current in the back channel. Further, by forming the region of the channel region where an electric current mainly flows using crystalline silicon, an electric characteristic of the channel region can be enhanced compared to a case where the channel region is formed using only amorphous silicon.

In manufacturing the thin film transistor having the constitution shown in FIG. 11, it is sufficient to change a part of the steps which are explained in conjunction with FIG. 5 to FIG. 9 as the manufacturing method of the transistor having the constitution shown in FIG. 4. To be more specific, it is sufficient that, in place of the formation of the semiconductor layer SL (FIG. 6), the formation of the crystalline silicon film and the formation of the amorphous silicon film are successively performed. Further, in place of the formation of a crystalline silicon film, an amorphous silicon film may be firstly formed and, thereafter, a crystalline silicon film is formed by crystallizing the amorphous silicon film.

FIG. 12 is a cross-sectional view showing a thin film transistor of another example (modification 3) according to an embodiment of the invention. Here, a planar shape of the thin film transistor in the modification 3 is substantially equal to the planar shape of the thin film transistor shown in FIG. 3. The modification 3 possesses both the characteristic of the modification 1 and the characteristic of the modification 2. That is, a main point which makes this modification different from the example shown in FIG. 4 lies in that a film which corresponds to the semiconductor film SC in the example shown in FIG. 4 is formed of a two-layered film consisting of a crystalline silicon film SF and an amorphous silicon film SA which is formed on the crystalline silicon film SP, and that a source semiconductor film SD is brought into contact with a side wall of the two-layered film on a left side of the drawing, and the drain semiconductor film DD is brought into contact with a side wall of the two-layered film on a right side of the drawing.

The structure of the thin film transistor of the modification 3 is specifically explained hereinafter. The structure below the gate insulation film GI is substantially equal to the corresponding structure of the example shown in FIG. 4. The two-layered film is formed by stacking the crystalline silicon film SP and the amorphous silicon film SA on a gate insulation film GI and above a gate electrode GT in this order. A first region which is brought into contact with the source semiconductor film SD is formed on a left portion of an upper surface of the amorphous silicon film SA, and a second region which is brought into contact with the drain semiconductor film DD is formed on a right portion of the upper surface of the amorphous silicon film SA. The first region and the second region are spaced apart from each other. The source semiconductor film SD has a right end thereof arranged on the first region, extends along a side wall of the two-layered film on a left side of the drawing in a contact state from the first region, and further extends on the gate insulation film GI toward a left side of the drawing from a lower end portion of the left side wall. The drain semiconductor film DD has a left end thereof arranged on the second region, extends along a side wall of the two-layered film on a right side of the drawing in a contact state from the second region, and further extends on the gate insulation film GI toward a right side of the drawing from a lower end portion of the right side wall. The source electrode ST is formed on the source semiconductor film SD, and the drain electrode DT is formed on the drain semiconductor film DD. Further, as viewed in a plan view, a portion of the gate electrode GT which overlaps with the semiconductor film SC overlaps with the first region and does not overlap with the second region. Here, the source electrode ST and the drain electrode DT are not brought into direct contact with the upper surface of the semiconductor film SC. A protective insulation film PA is formed so as to cover the above-described structure.

By adopting the constitution shown in FIG. 12, this modification 3 can acquire both an advantageous effect that an ON current can be increased as in the case of the modification 1 and an advantageous effect that a leak current from the back channel can be suppressed as in the case of the modification 2. In manufacturing the thin film transistor having the structure shown in FIG. 12, it is sufficient to change a part of the steps which are explained in conjunction with FIG. 5 to FIG. 9 as the manufacturing method of the thin film transistor having the constitution shown in FIG. 4. The point which makes this modification 3 different from the example shown in FIG. 4 is roughly classified into the following two points. One point is that the formation of the crystalline silicon film and the formation of the amorphous silicon film are performed successively in place of the formation of the semiconductor layer SL (FIG. 6), and the other point is that patterning of the two-layered film and the formation of an impurity-diffused semiconductor film DS are performed after the formation of the two-layered film. Thereafter, steps corresponding to the steps explained in conjunction with FIG. 8 and succeeding drawings may be performed.

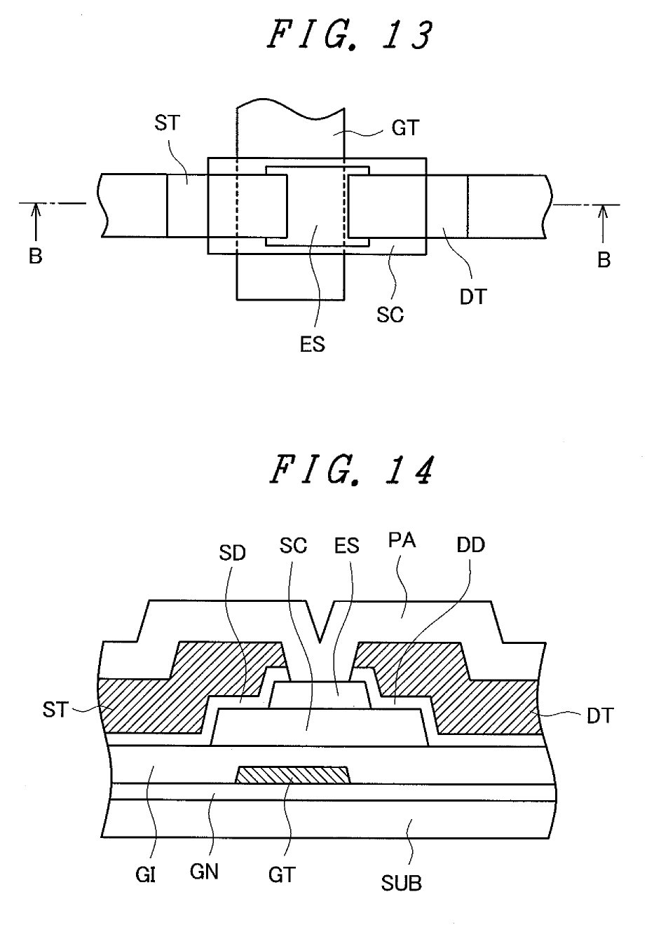

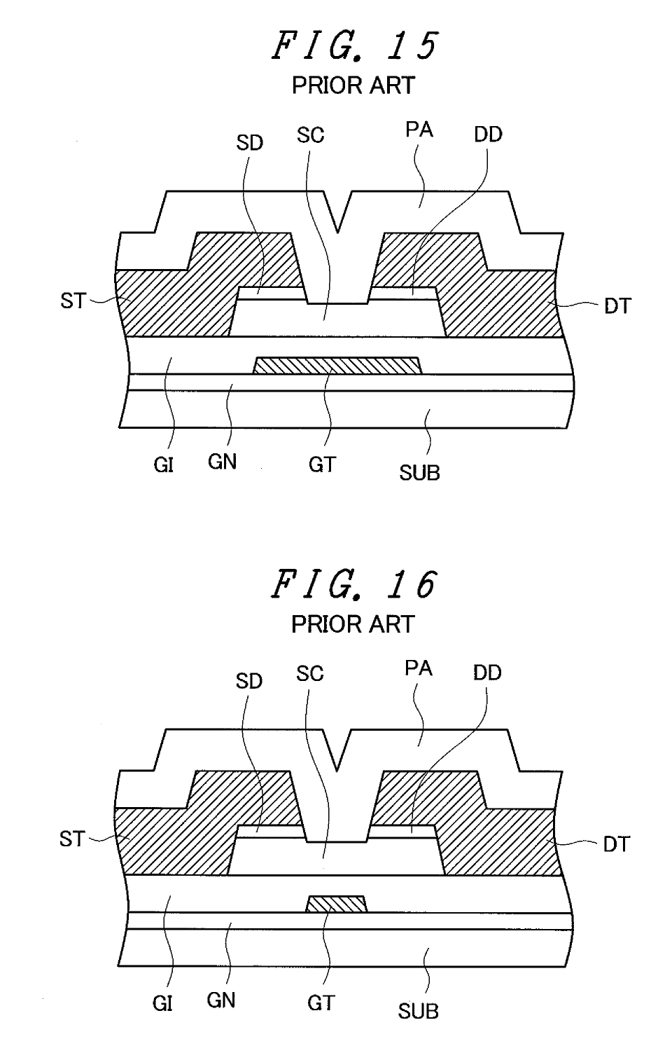

FIG. 13 is a plan view showing a thin film transistor of another example (modification 4) according to the embodiment of the invention. FIG. 14 is a cross-sectional view of the thin film transistor taken along a line B-B in FIG. 13. A main point which makes the modification 4 different from the modification 1 lies in that a channel etching stopper film ES is formed on a semiconductor film SC. The modification 4 is substantially equal to other modifications with respect to the structure below a gate insulation film GI and the structure in which a semiconductor film SC is formed on a gate insulation film GI. On an upper surface of the semiconductor film SC, the channel etching stopper film ES is formed in a region which extends between a first region which is in contact with the source semiconductor film SD and a second region which is in contact with the drain semiconductor film DD. The channel etching stopper film ES is formed using a material (for example, silicon oxide) which cannot be etched at the time of etching the source electrode ST, the source semiconductor film SD and the like.

The source semiconductor film SD is formed on the upper surface of the semiconductor film SC in a state where the source semiconductor film SD is brought into contact with the first region on a left side of the channel etching stopper film ES. The source semiconductor film SD extends toward a right side from a portion thereof which is brought into contact with the first region, gets over a side wall of the channel etching stopper film ES, and reaches an upper surface of the channel etching stopper film ES. The source semiconductor film SD also extends along a side wall of the semiconductor film SC on a left side of the drawing in a contact state toward a left side from the portion thereof which is brought into contact with the first region. Further, the source semiconductor film SD extends on the gate insulation film GI toward a left side of the drawing from an area in the vicinity of a lower end of the side wall.

The drain semiconductor film DD is formed on the upper surface of the semiconductor film SC in a state that the drain semiconductor film DD is brought into contact with the second region on a right side of the channel etching stopper film ES. The drain semiconductor film DD extends toward a left side from a portion thereof which is brought into contact with the second region, gets over a side wall of the channel etching stopper film ES, and reaches the upper surface of the channel etching stopper film ES. The drain semiconductor film DD also extends along a side wall of the semiconductor film SC on a right side of the drawing in a contact state toward a right side from the portion thereof which is brought into contact with the second region. Further, the drain semiconductor film DD extends on the gate insulation film GI toward a right side of the drawing from an area in the vicinity of a lower end of the side wall. Here, the source semiconductor film SD and the drain semiconductor film DD are spaced apart from each other. Further, the source electrode SD is formed on the source semiconductor film SD, and the drain electrode DT is formed on the drain semiconductor film DD. The gate electrode GT overlaps with the first region as viewed in a plan view and does not overlap with the second region as viewed in a plan view.

In manufacturing the thin film transistor having the structure shown in FIG. 13 and FIG. 14, it is sufficient to change a part of the steps which are explained in conjunction with FIG. 5 to FIG. 9 as the manufacturing method of the thin film transistor having the constitution shown in FIG. 4. To be more specific, after forming the semiconductor layer SL (FIG. 6), patterning of the semiconductor layer SL is performed and, further, an insulation layer made of silicon oxide or the like is formed and is patterned for forming the channel etching stopper film ES, for example. Alternatively, after forming the semiconductor layer SL (FIG. 6), the channel etching stopper film ES is formed and is patterned and, thereafter, the semiconductor layer SL is patterned. Then, the impurity-diffused semiconductor film DS is formed, and is further patterned. Thereafter, steps corresponding to the steps explained in conjunction with FIG. 8 and succeeding drawings may be performed.

The modification 4 differs from other modifications with respect to a point that a position of the first region and a position of the second region on the semiconductor film SC are determined based on patterning of the channel etching stopper film ES and a point that the channel etching stopper film ES prevents the semiconductor film SC from being etched at the time of performing etching for forming the source electrode ST and the drain electrode DT.

Although the embodiment of the invention has been explained heretofore, the invention is not limited to the above-mentioned embodiment. For example, although the explanation has been made mainly with respect to the n-channel-type thin film transistor in the embodiment of the invention, the invention is also applicable to a p-channel-type thin film transistor. Also in the p-channel-type thin film transistor, a portion of a gate electrode GT which overlaps with a semiconductor film SC or the like as viewed in a plan view is arranged closer to a first region than a second region. Further, impurities such as boron are diffused in the source semiconductor film SD and the drain semiconductor film DD thus forming a p-type semiconductor.

Further, this embodiment exemplifies the case where the display device is a vertical-electric-field type liquid crystal display device such as a TN-type liquid crystal display device. However, the invention is also applicable to a lateral-electric-field type liquid crystal display device such as an IPS-type liquid crystal display device. This is because the difference in type of display device does not become an obstacle for the lateral-electric-field type liquid crystal display device to adopt the substantially same structure in the thin film transistor. Further, the invention is also applicable to a pixel transistor of an organic EL display device. In this case, the invention is more effectively applicable to a top-emission-type pixel transistor which prevents light from being incident on the transistor.

What is claimed is:

1. A display device comprising:
an insulation substrate; and
thin film transistors which are formed on the insulation substrate, wherein
each thin film transistor includes:
a conductive layer on which a gate electrode is formed;
a first insulation layer which is formed on the conductive layer;
a semiconductor layer which is formed on the first insulation layer and has a first semiconductor film thereof formed above the gate electrode, the first semiconductor film having a first region and a second region which are spaced apart from each other on an upper surface thereof;
a first electrode which is connected to the upper surface of the first semiconductor film via the first region; and
a second electrode which is connected to the upper surface of the first semiconductor film via the second region; wherein
a portion of the gate electrode which is covered with the first semiconductor film is arranged closer to the first region than the second region.

2. A display device according to claim 1, wherein the gate electrode overlaps with the first region as viewed in a plan view and does not overlap with the second region as viewed in a plan view.

3. A display device according to claim 1, wherein the first semiconductor film is made of a material which contains poly-crystalline silicon or micro-crystalline silicon.

4. A display device according to claim 1, wherein the first electrode is connected to the upper surface of the first semiconductor film via a second semiconductor film formed on the first region, and
the second electrode is connected to the upper surface of the first semiconductor film via a third semiconductor film formed on the second region.

5. A display device according to claim 4, wherein impurities are diffused in the second semiconductor film and the third semiconductor film.

6. A display device according to claim 5, wherein at least one of the first electrode and the second electrode is connected to a side surface of the first semiconductor film via a semiconductor film in which the impurities are diffused.

7. A display device according to claim 1, wherein the first electrode is a source electrode of the thin film transistor, and
the second electrode is a drain electrode of the thin film transistor.

8. A display device according to claim 1, wherein the first semiconductor film is formed of two layers consisting of a poly-crystalline silicon film and an amorphous silicon film stacked from a first insulation layer side.

9. A display device according to claim 1, wherein the first semiconductor film is formed of two layers consisting of a micro-crystalline silicon film and an amorphous silicon film stacked from a first insulation layer side.

10. A display device according to claim 1, wherein an insulation film is formed on an upper layer of a region sandwiched by the first region and the second region.

11. A display device according to claim 1, wherein a display region which includes a plurality of pixels and a peripheral region which surrounds the display region are formed on the insulation substrate, and the thin film transistor is formed on the peripheral region.

12. A display device according to claim 11, wherein
the pixel includes a plurality of sub pixels, and
the thin film transistor is a changeover switch which selects a sub pixel to which a video signal is inputted out of the plurality of sub pixels.

13. A display device according to claim 12, wherein the first electrode is connected to the sub pixel, and a video signal is inputted to the second electrode.
